(19) United States
(12) Patent Application Publication
(10) Pub. No.: US 2026/0103789 A1
(43) Pub. Date: Apr. 16, 2026

(54) MASK ASSEMBLY, METHOD OF MANUFACTURING THE SAME AND ELECTRONIC DEVICE MANUFACTURED USING THE SAME

(71) Applicant: Samsung Display Co., LTD., Yongin-si (KR)

(72) Inventors: Young Jin SONG, Yongin-si (KR); Hyeong Pil KIM, Yongin-si (KR); Seung Kyu PARK, Yongin-si (KR)

(73) Assignee: Samsung Display Co., LTD., Yongin-si (KR)

(21) Appl. No.: 19/259,125

(22) Filed: Jul. 3, 2025

(30) Foreign Application Priority Data
Oct. 10, 2024 (KR) 10-2024-0137799

(51) Int. Cl. C23C 14/04; H10K 71/16

(52) U.S. Cl. CPC C23C 14/042; H10K 71/166

(57) ABSTRACT

Provided is a mask assembly that includes a mask frame and a mask. The mask frame includes a first opening portion and also includes a first portion doped with an N-dopant. The mask is disposed on the mask frame and includes a plurality of second opening portions overlapping the first opening portion.

### CROSS-REFERENCE TO RELATED APPLICATION(S)

This application claims priority to and the benefits of Korean Patent Application No. 10-2024-0137799 under 35 U.S.C. § 119, filed Oct. 10, 2024, the entire contents of which are incorporated herein by reference.

### BACKGROUND

### 1. Technical Field

Embodiments relate to a mask assembly. Specifically, the embodiments relate to a mask assembly, a method of manufacturing the mask assembly and an electronic device formed by the mask assembly.

### 2. Description of the Related Art

Recently, as interest in an information display has been increasing, research and development on a mask assembly manufacturing a display device have been continuously conducted.

### SUMMARY

An object to be solved is to provide a method of manufacturing a mask assembly with improved production yield.

Another object to be solved is to provide a mask assembly manufactured by the method of manufacturing the mask assembly.

Objects of the disclosure are not limited to the object described above, and other technical objects which are not described may be clearly understood by those skilled in the art from the description below.

According to embodiments of the disclosure, a mask assembly includes a mask frame including a first opening portion and including a first portion doped with an N-dopant, and a mask disposed on the mask frame and including a plurality of second opening portions overlapping the first opening portion.

In embodiment, the first portion may be in direct contact with the mask.

In embodiment, the mask may include silicon nitride.

In embodiment, the mask frame may include a base layer, a silicon wafer disposed on the base layer, and an oxide layer disposed on the silicon wafer and including silicon oxide.

In embodiment, the first portion may be included in the oxide layer.

In embodiment, the oxide layer may include a first opening, the base layer may include a second opening overlapping the first opening, and the silicon wafer may include a third opening overlapping the second opening.

In embodiment, the first opening portion may include the first, second, and third openings.

In embodiment, the base layer may include a first layer disposed on a first surface of the silicon wafer, and a second layer disposed under the first layer.

In embodiment, the first layer may include silicon oxide, and the second layer may include silicon nitride.

In embodiment, the first portion may be doped with phosphorus (P).

According to embodiments, a method of manufacturing a mask assembly may include forming a mask frame including a first opening portion and including a first portion doped with an N-dopant, and forming a mask including a plurality of second opening portions overlapping the first opening portion on the mask frame.

In embodiment, the forming of the mask frame may include forming a preliminary silicon wafer, forming a first layer including silicon oxide on a first surface of the preliminary silicon wafer, oxidizing a second surface of the preliminary silicon wafer to form a first oxide layer, removing a portion of the first oxide layer to form a first opening exposing a doping area of the second surface of the preliminary silicon wafer, doping a surface of the first oxide layer and the doping area of the second surface of the preliminary silicon wafer with the N-dopant, and oxidizing the doping area of the second surface to form a second oxide layer.

In embodiment, the N-dopant may be phosphorus (P).

In embodiment, the forming of the mask may include after forming the second oxide layer, forming a preliminary mask on the first oxide layer and the second oxide layer, forming a photoresist pattern on the preliminary mask, and patterning the preliminary mask using the photoresist pattern to form the mask.

In embodiment, the forming of the mask frame may further include forming a second layer under the first layer, and patterning a portion overlapping the doping area in each of the first layer and the second layer to form a second opening overlapping the first opening.

In embodiment, the first layer may include silicon oxide, and the second layer may include silicon nitride.

In embodiment, the forming of the mask frame may further include after forming the mask, patterning a portion overlapping the doping area of the preliminary silicon wafer to form a silicon wafer having a third opening overlapping the second opening, and removing the second oxide layer.

An electronic device may include a processor; and a display device including pixels, and that displays an image on the pixels according to control of the processor, wherein the display device may be formed by a mask assembly comprising: a mask frame including a first opening portion and including a first portion doped with an N-dopant; and a mask disposed on the mask frame and including a plurality of second opening portions overlapping the first opening portion.

Specific details of other embodiments are included in the detailed description and drawings.

According to the embodiment described above, by doping a portion of the preliminary silicon wafer with the N-dopant having an etching speed higher than an etching speed of intrinsic silicon, a deviation of a removal speed for each area may be minimized at the doping area of the preliminary silicon wafer. In addition, because the deviation of the removal speed for each area may be minimized, a stress difference between configurations occurring due to a deviation of an etching speed may also be minimized. Accordingly, damage to the mask assembly may be prevented, and a yield of the mask assembly may be improved.

An effect according to embodiments is not limited to the contents described above, and more various effects are included in the specification.

### BRIEF DESCRIPTION OF THE DRAWINGS

The above and other features of the disclosure will become more apparent by describing in further detail embodiments thereof with reference to the accompanying drawings, in which:

FIG. 1 is a schematic cross-sectional view of deposition equipment;

FIG. 2 is a schematic plan view of a display panel formed using the deposition equipment of FIG. 1;

FIG. 3 is an exploded schematic perspective view illustrating a portion of the display panel of FIG. 2;

FIG. 4 is a schematic plan view of a mask assembly according to embodiments of the disclosure;

FIG. 5 is an exploded schematic perspective view of the mask assembly of FIG. 4;

FIG. 6 is a schematic cross-sectional view taken along line I-I′ of FIG. 4; and

FIGS. 7 to 19 are schematic drawings illustrating a method of manufacturing a mask assembly according to embodiments of the disclosure.

FIG. 20 is a schematic block diagram illustrating an embodiment of an electronic device including the display device of FIGS. 2 and 3.

FIG. 21 is a schematic perspective view illustrating an example of a smartphone that may be implemented using the electronic device of FIG. 20.

FIG. 22 is a schematic perspective view illustrating an example of a tablet computer that may be implemented using the electronic device of FIG. 20.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z -axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. For example, “about” may mean within one or more standard deviations, or within ±20%, ±10%, or ±5% of the stated value.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

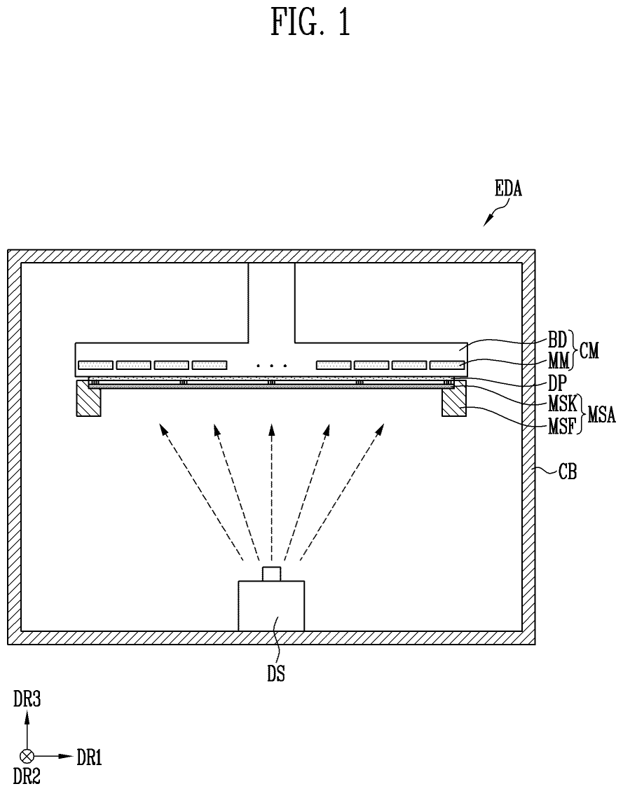

FIG. 1 is a schematic cross-sectional view of deposition equipment.

Referring to FIG. 1, the deposition equipment EDA according to an embodiment of the disclosure may include a deposition chamber CB, a fixing member CM, a deposition source DS disposed inside the deposition chamber CB, and a mask assembly MSA disposed inside the deposition chamber CB. For example, the deposition equipment EDA may further include an additional mechanical device for implementing an inline system.

The deposition chamber CB may set a deposition condition to vacuum. The deposition chamber CB may include a floor surface, a ceiling surface, and side walls. The floor surface of the deposition chamber CB may be parallel to a plane defined by a first direction DR1 and a second direction DR2. A normal direction of the floor surface of the deposition chamber CB points to a third direction DR3.

The fixing member CM may be disposed inside the deposition chamber CB, may be disposed on the deposition source DS, and may fix the mask assembly MSA. The fixing member CM may be installed on the ceiling surface of the deposition chamber CB. The fixing member CM may include a jig or a robot arm holding the mask assembly MSA.

The fixing member CM may include a support BD and magnetic materials MM coupled to the support BD. The support BD may include a plate as a basic structure for fixing the mask assembly MSA, but embodiments are not limited thereto. The magnetic materials MM may be disposed inside or outside the support BD. The magnetic materials MM may fix the mask assembly MSA with magnetic force.

The deposition source DS may evaporate a deposition material and eject the deposition material as a deposition vapor. The deposition vapor may pass through the mask assembly MSA and may be deposited on a display panel DP in a predetermined (or certain) pattern. The display panel DP may be defined as a substrate of an intermediate stage manufacturing a completed display panel DP described later.

The mask assembly MSA may be disposed inside the deposition chamber CB, may be disposed on the deposition source DS, and may support the display panel DP. The display panel DP may include a glass substrate, a plastic substrate, or a silicon substrate. The display panel DP may include a polymer layer disposed on a base substrate.

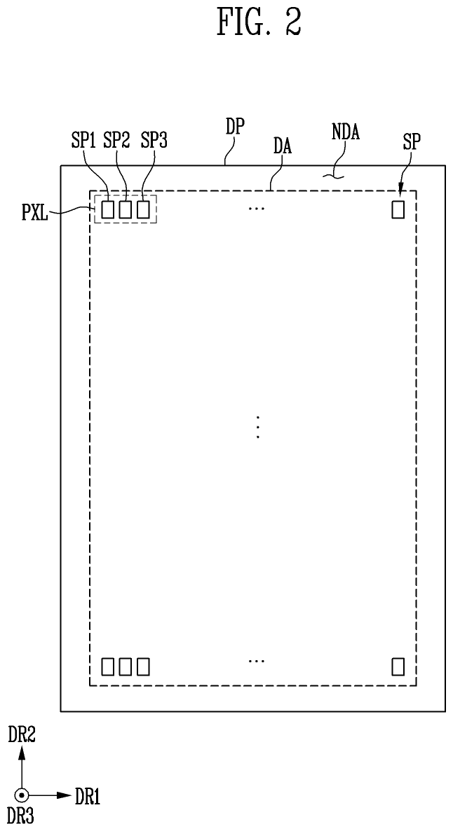

FIG. 2 is a schematic plan view of a display panel formed using the deposition equipment of FIG. 1.

Referring to FIG. 2, the display panel DP may include a display area DA and a non-display area NDA. The display panel DP may display an image through the display area DA. The non-display area NDA may be disposed around the display area DA.

The display panel DP may include a substrate SUB and sub-pixels SP.

The display panel DP may be positioned very close to user's eyes in case that the display panel DP is used as a display screen of a head mounted display (HMD), a virtual reality (VR) device, a mixed reality (MR) device, an augmented reality (AR) device, or the like. For example, sub-pixels SP of a relatively high integration degree are required. To increase an integration degree of the sub-pixels SP, the substrate SUB may be provided (or formed) as a silicon substrate. The sub-pixels SP and/or the display panel DP may be formed on the substrate SUB, which is the silicon substrate. A display device including the display panel DP formed on the substrate SUB, which is the silicon substrate, may be referred to as an organic light-emitting diode (OLED) on silicon (OLEDoS) display device.

The sub-pixels SP may be disposed in the display area DA on the substrate SUB. The sub-pixels SP may be arranged in a matrix shape along the first direction DR1 and the second direction DR2 intersecting the first direction DR1. However, embodiments are not limited thereto. For example, the sub-pixels SP may be arranged in a zigzag shape along the first direction DR1 and the second direction DR2. The first direction DR1 may be a row direction, and the second direction DR2 may be a column direction. Two or more sub-pixels among the sub-pixels SP may form a pixel (e.g., single pixel) PXL.

A component for controlling the sub-pixels SP may be disposed in the non-display area NDA on the substrate SUB. For example, lines connected to the sub-pixels SP, such as gate lines transmitting a gate signal and data lines transmitting a data signal, may be disposed in the non-display area NDA.

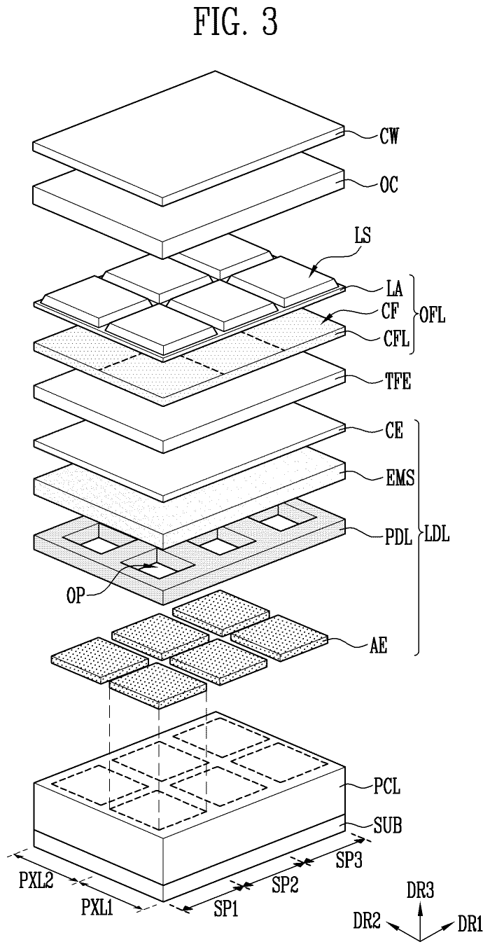

FIG. 3 is an exploded schematic perspective view illustrating a portion of the display panel of FIG. 2. In FIG. 3, for clarify and concise description, a portion of the display panel DP corresponding to two pixels PXL1 and PXL2 among the pixels PXL of FIG. 2 is schematically shown. A portion of the display panel DP corresponding to remaining pixels may be similarly configured.

Referring to FIGS. 2 and 3, each of the first and second pixels PXL1 and PXL2 may include first to third sub-pixels SP1, SP2, and SP3.

The display panel DP may include a substrate SUB, a pixel circuit layer PCL, a light emitting element layer LDL, an encapsulation layer TFE, an optical function layer OFL, an overcoat layer OC, and a cover window CW.

In embodiments, the substrate SUB may include a silicon wafer substrate formed by a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, or the like. In other embodiments, the substrate SUB may include a glass substrate. In still other embodiments, the substrate SUB may include a polyimide (PI) substrate.

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may function as at least a portion of circuit elements, lines, and the like. The conductive patterns may include copper, but embodiments are not limited thereto.

The circuit elements may include a sub-pixel circuit for each of the first to third sub-pixels SP1, SP2, and SP3. The sub-pixel circuit may include transistors and one or more capacitors. Each transistor may include a semiconductor portion including a source area, a drain area, and a channel area, and a gate electrode overlapping the semiconductor portion. In embodiments, the semiconductor portion may be included in the substrate SUB, and the gate electrode may be included in the pixel circuit layer PCL as a conductive pattern of the pixel circuit layer PCL, in case that the substrate SUB is provided (or formed) as a silicon substrate. In embodiments, the semiconductor portion and the gate electrode may be included in the pixel circuit layer PCL in case that the substrate SUB is provided (or formed) as a glass substrate or a polymide (PI) substrate. Each capacitor may include electrodes spaced apart from each other. For example, each capacitor may include electrodes spaced apart from each other on a plane defined by the first and second directions DR1 and DR2. For example, each capacitor may include electrodes spaced apart from each other in the third direction DR3 with an insulating layer interposed between the electrodes.

The lines of the pixel circuit layer PCL may include signal lines connected to each of the first to third sub-pixels SP1, SP2, and SP3, for example, a gate line, an emission control line, a data line, and the like. The lines may further include a line connected to a first power voltage node. For example, the lines may further include a line connected to a second power voltage node.

The light emitting element layer LDL may include the anode electrodes AE, a pixel defining layer PDL, a light emitting structure EMS, and the cathode electrode CE.

The anode electrodes AE may be disposed on the pixel circuit layer PCL. The anode electrodes AE may contact the circuit elements of the pixel circuit layer PCL. The anode electrodes AE may include an opaque conductive material capable of reflecting light, but embodiments are not limited thereto.

The pixel defining layer PDL may be disposed on the anode electrodes AE. The pixel defining layer PDL may include an opening OP exposing a portion of each of the anode electrodes AE. According to the opening OP of the pixel defining layer PDL, emission areas respectively corresponding to the first to third sub-pixels SP1, SP2, and SP3 may be defined. In another example, it may be understood that the emission areas corresponding to the first to third sub-pixels SP1, SP2, and SP3 are defined according to the anode electrodes AE. In an area adjacent to a boundary between neighboring sub-pixels, the pixel defining layer PDL may include a separator that causes formation of a discontinuous portion (or discontinuity) in the light emitting structure EMS. For example, it may be understood that the emission areas respectively corresponding to the first to third sub-pixels SP1, SP2, and SP3 are defined according to the separators of the pixel defining layer PDL.

In embodiments, the pixel defining layer PDL may include an inorganic material. For example, the pixel defining layer PDL may include stacked inorganic layers. For example, the pixel defining layer PDL may include silicon oxide (SiOx) and silicon nitride (SiNx). In other embodiments, the pixel defining layer PDL may include an organic material. However, a material of the pixel defining layer PDL is not limited thereto.

The light emitting structure EMS may be disposed on the anode electrodes AE exposed by the opening OP of the pixel defining layer PDL. The light emitting structure EMS may include a light emitting layer that generates light, an electron transport layer that transports an electron, a hole transport layer that transports a hole, and the like.

In embodiments, the light emitting structure EMS may fill the opening OP of the pixel defining layer PDL, and may be disposed (e.g., entirely disposed) on the pixel defining layer PDL. For example, the light emitting structure EMS may extend across the first to third sub-pixels SP1, SP2, and SP3. For example, at least a portion of layers in the light emitting structure EMS may be disconnected or bent at boundaries between the first to third sub-pixels SP1, SP2, and SP3. However, embodiments are not limited thereto. For example, portions of the light emitting structure EMS corresponding to the first to third sub-pixels SP1, SP2, and SP3 may be separated from each other, and each of the portions may be disposed in the opening OP of the pixel defining layer PDL.

The cathode electrode CE may be disposed on the light emitting structure EMS. The cathode electrode CE may extend across the first to third sub-pixels SP1, SP2, and SP3. As described above, the cathode electrode CE may be provided (or formed) as a common electrode for the first to third sub-pixels SP1, SP2, and SP3.

The cathode electrode CE may be a thin metal layer having a thickness sufficient to transmit light emitted from the light emitting structure EMS. The cathode electrode CE may include a metal material or a transparent conductive material to have a relatively thin thickness. In embodiments, the cathode electrode CE may include at least one of various transparent conductive materials including indium tin oxide, indium zinc oxide, indium tin zinc oxide, aluminum zinc oxide, gallium zinc oxide, zinc tin oxide, or gallium tin oxide. In other embodiments, the cathode electrode CE may include at least one of silver (Ag), magnesium (Mg), or a mixture thereof. However, a material of the cathode electrode CE is not limited thereto.

It may be understood that any of the anode electrodes AE, a portion of the light emitting structure EMS overlapping the anode electrodes AE, and a portion of the cathode electrode CE overlapping the anode electrodes AE form one light emitting element. For example, each of the light emitting elements of the first to third sub-pixels SP1, SP2, and SP3 may be an anode electrode, a portion of the light emitting structure EMS overlapping the anode electrode, and a portion of the cathode electrode CE overlapping the anode electrode. In each of the first to third sub-pixels SP1, SP2, and SP3, holes injected from the anode electrode AE and electrons injected from the cathode electrode CE may be transported into the light emitting layer of the light emitting structure EMS to form excitons, and light may be generated in case that the excitons transits from an excited state to a ground state. A luminance of light may be determined according to an amount of a current flowing through the light emitting layer. According to a configuration of the light emitting layer, a wavelength range of the generated light may be determined.

The encapsulation layer TFE may be disposed on the cathode electrode CE. The encapsulation layer TFE may cover the light emitting element layer LDL and/or the pixel circuit layer PCL. The encapsulation layer TFE may prevent oxygen, moisture, and/or the like from permeating to the light emitting element layer LDL. In embodiments, the encapsulation layer TFE may include a structure in which one or more inorganic layers and one or more organic layers are alternately stacked. For example, the inorganic layer may include silicon nitride, silicon oxide, silicon oxynitride (SiOₓN_{y}), or the like. For example, the organic layer may include an organic insulating material such as acrylic resin, epoxy resin, phenol resin, polyamide resin, polyimide resin, unsaturated polyester resin, polyphenylenether resin, polyphenylenesulfide resin, or benzocyclobutene (BCB). However, materials of the organic layer and the inorganic layer of the encapsulation layer TFE are not limited thereto.

To improve an encapsulation efficiency of the encapsulation layer TFE, the encapsulation layer TFE may further include a thin film including aluminum oxide (AlOₓ). The thin film including the aluminum oxide may be positioned on an upper surface of the encapsulation layer TFE facing the optical functional layer OFL and/or a lower surface of the encapsulation layer TFE facing the light emitting element layer LDL.

The thin film including the aluminum oxide may be formed by an atomic layer deposition (ALD) method. However, embodiments are not limited thereto. The encapsulation layer TFE may further include a thin film including at least one of various materials suitable for improving the encapsulation efficiency.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter the light emitted from the light emitting structure EMS and selectively output light of a wavelength range or a color corresponding to each sub-pixel. The color filter layer CFL may include color filters CF respectively corresponding to the first to third sub-pixels SP1, SP2, and SP3, and each of the color filters CF may pass light of a wavelength range corresponding to the corresponding sub-pixel. For example, the color filter corresponding to the first sub-pixel SP1 may pass red color light, the color filter corresponding to the second sub-pixel SP2 may pass green color light, and the color filter corresponding to the third sub-pixel SP3 may pass blue color light. According to the light emitted from the light emitting structure EMS of each sub-pixel, at least a portion of the color filters CF may be omitted.

The lens array LA may be disposed on the color filter layer CFL. The lens array LA may include lenses LS corresponding to the first to third sub-pixels SP1, SP2, and SP3, respectively. Each of the lenses LS may improve light emission efficiency by outputting light emitted from the light emitting structure EMS to an intended path. The lens array LA may have a relatively high refractive index. For example, the lens array LA may have a refractive index higher than that of the overcoat layer OC. In embodiments, the lenses LS may include an organic material. In embodiments, the lenses LS may include an acrylic material. However, a material of the lenses LS is not limited thereto.

The overcoat layer OC may be disposed on the lens array LA. The overcoat layer OC may cover the optical functional layer OFL, the encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer or an organic insulating layer. For example, the overcoat layer OC may include epoxy, but embodiments are not limited thereto. The overcoat layer OC may have a refractive index lower than that of the lens array LA.

The cover window CW may be disposed on the overcoat layer OC. The cover window CW may protect layers thereunder. The cover window CW may have a refractive index higher than that of the overcoat layer OC. The cover window CW may include glass, but embodiments are not limited thereto. For example, the cover window CW may be an encapsulation glass that protects components disposed thereunder. In other embodiments, the cover window CW may be omitted.

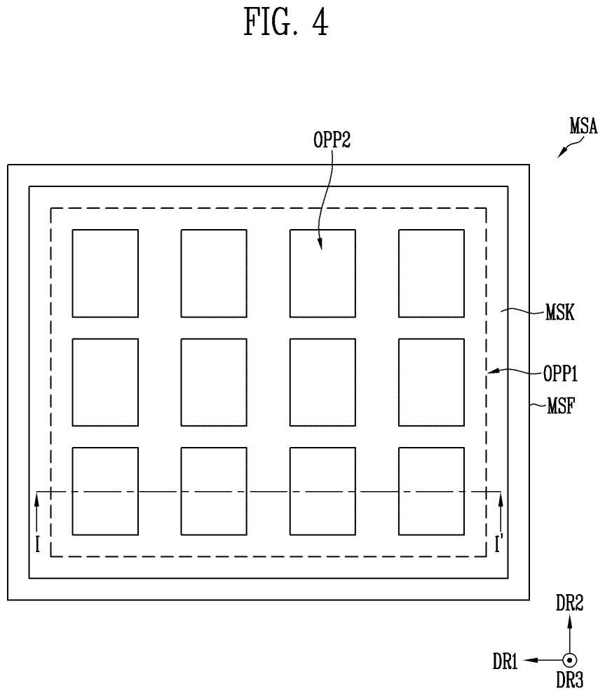

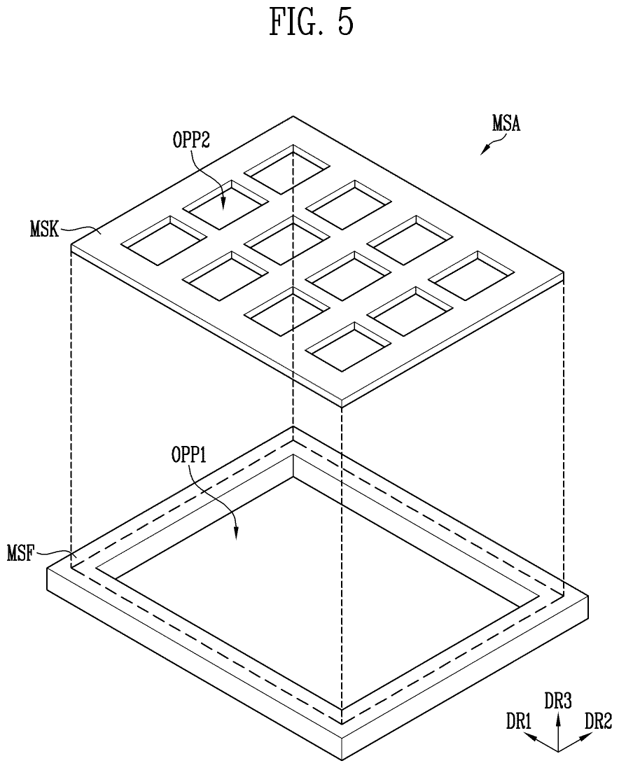

FIG. 4 is a schematic plan view of a mask assembly according to embodiments of the disclosure. FIG. 5 is an exploded schematic perspective view of the mask assembly of FIG. 4.

Referring to FIGS. 4 and 5, the mask assembly MSA may include a mask frame MSF and a mask MSK. The mask assembly MSA may be used for deposition of components of the display device of FIG. 3. In embodiments, the mask assembly MSA may be used to form a thin film layer including a same material on a target substrate, which is a deposition surface. For example, the mask assembly MSA may include an open mask for a thin film process used to form a functional layer provided (or formed) as a thin film. The open mask for the thin film process may be a mask used to stack a thin film layer of a same material over an entire individual display device on the target substrate.

The mask frame MSF may support the mask MSK. For example, the mask frame MSF may support an edge of the mask MSK. The mask MSK may be fixed to the mask frame MSF.

The mask frame MSF may define (or include) a first opening portion OPP1. The first opening portion OPP1 may overlap the mask MSK and expose the mask MSK.

The mask MSK may be disposed on the mask frame MSF. The mask MSK may define (or include) second opening portions OPP2. The second opening portions OPP2 may overlap the first opening portion OPP1, and the second opening portions OPP2 may be exposed through the first opening portion OPP1.

The second opening portions OPP2 may be defined by being aligned on the plane defined by the first direction DR1 and the second direction DR2. FIG. 4 illustrates an embodiment of the mask MSK in which four second opening portions OPP2 are defined spaced apart from each other along the first direction DR1 and three second opening portions OPP2 are defined spaced apart from each other along the second direction DR2. However, this is an example, and the number of second opening portions OPP2 is not limited to that shown. The second opening portions OPP2 may be arranged to have a constant distance along one of the first direction DR1 or the second direction DR2. A material forming a thin film layer may be deposited on the target substrate through each of the second opening portions OPP2.

The mask MSK may have a plate shape extending along the first direction DR1 and the second direction DR2. In an embodiment, the mask MSK may have a quadrangular shape in a plan view defined by the first direction DR1 and the second direction DR2. However, embodiments are not limited thereto, and a shape of the mask MSK may be provided by being modified into another shape according to a shape of the target substrate, a shape of the mask frame MSF supporting the mask MSK, or the like.

For example, in the mask MSK of an embodiment, the second opening portions OPP2 may have a quadrangular shape in a plan view. However, an embodiment is not limited thereto, and a shape of each of the second opening portions OPP2 may be modified to have various shapes according to a shape of the thin film layers deposited and formed on the target substrate.

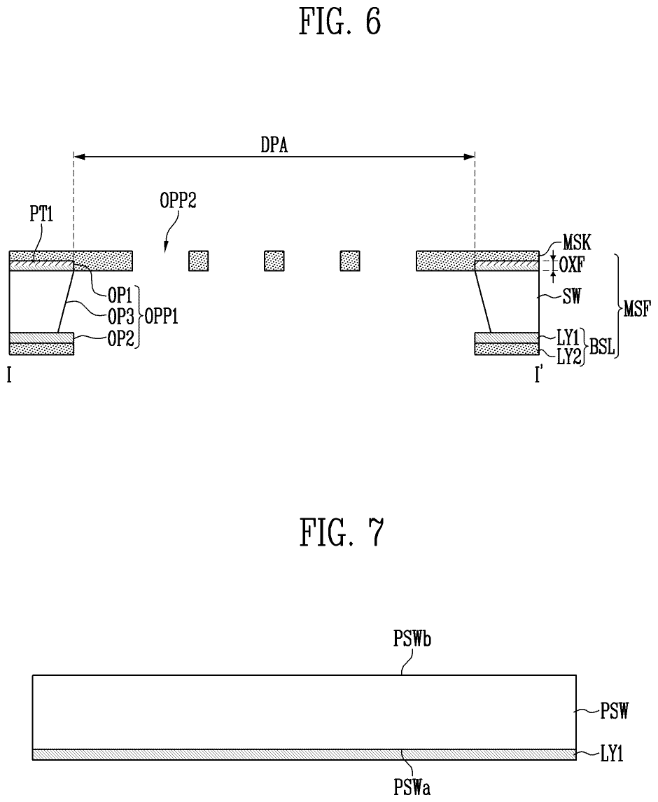

FIG. 6 is a schematic cross-sectional view taken along line I-I′ of FIG. 4.

Referring to FIG. 6, the mask frame MSF may include a base layer BSL, a silicon wafer SW, and an oxide layer OXF.

The base layer BSL may include a first layer LY1 disposed on a first surface of the silicon wafer SW and a second layer LY2 disposed under the first layer LY1. The first layer LY1 may include silicon oxide, and the second layer LY2 may include silicon nitride.

The silicon wafer SW may be disposed on the base layer BSL. The silicon wafer SW may include silicon.

The oxide layer OXF may be disposed between the silicon wafer SW and the mask MSK. The oxide layer OXF may be in contact with (e.g., in direct contact with) the mask MSK. The oxide layer OXF may include silicon oxide formed by oxidizing silicon.

The oxide layer OXF may define (or include) a first opening OP1 overlapping the second opening portions OPP2 of the mask MSK. The base layer BSL may define (or include) a second opening OP2 overlapping the first opening OP1. The silicon wafer SW may define (or include) a third opening OP3 overlapping the second opening OP2. The first to third openings OP1 to OP3 may configure (or form) the first opening portion OPP1.

For example, a planar surface area (or size) of the third opening OP3 at an interface where the base layer BSL and the silicon wafer SW contact may be greater than a planar surface area (or size) of the second opening OP2. For example, at the interface where the base layer BSL and the silicon wafer SW contact, the base layer BSL may have a shape protruding in an inward direction of the first opening portion OPP1 compared to the silicon wafer SW. For example, the base layer BSL and the silicon wafer SW may form an undercut structure.

In embodiments, the mask frame MSF may include a first portion PT1 doped with an N-dopant (or N-type dopant). For example, the N-dopant may be at least one of phosphorus (P), arsenic (As), or antimony (Sb). For example, the N-dopant may be phosphorus (P). For example, the first portion PT1 may be a portion doped to an N-type by phosphorus (P). The first portion PT1 may be a portion formed by remaining a doped portion during a manufacturing process of the mask assembly MSA described later with reference to FIGS. 7 to 19.

The first portion PT1 may be in contact with (e.g., in direct contact with) the mask MSK. For example, the first portion PT1 may be included in the oxide layer OXF which is in contact with the mask MSK. The first portion PT1 may be defined as a portion in which an upper portion of the oxide layer OXF is doped with an N-dopant. For example, because the oxide layer OXF includes silicon oxide rather than silicon, conductivity of the oxide layer OXF may not be significantly improved due to the N-type doping. Hereinafter, in the specification, a meaning that a specific layer is doped with an N-dopant may include a meaning that an N-type dopant collides with a corresponding layer and is embedded (included) in the corresponding layer.

The mask MSK may be disposed on the oxide layer OXF. The mask MSK may include silicon nitride.

FIGS. 7 to 19 are schematic drawings illustrating a method of manufacturing a mask assembly according to embodiments of the disclosure.

Referring to FIG. 7, a preliminary silicon wafer PSW may be formed. The preliminary silicon wafer PSW may include silicon.

A first layer LY1 may be formed on a first surface PSWa of the preliminary silicon wafer PSW. The first layer LY1 may include silicon oxide.

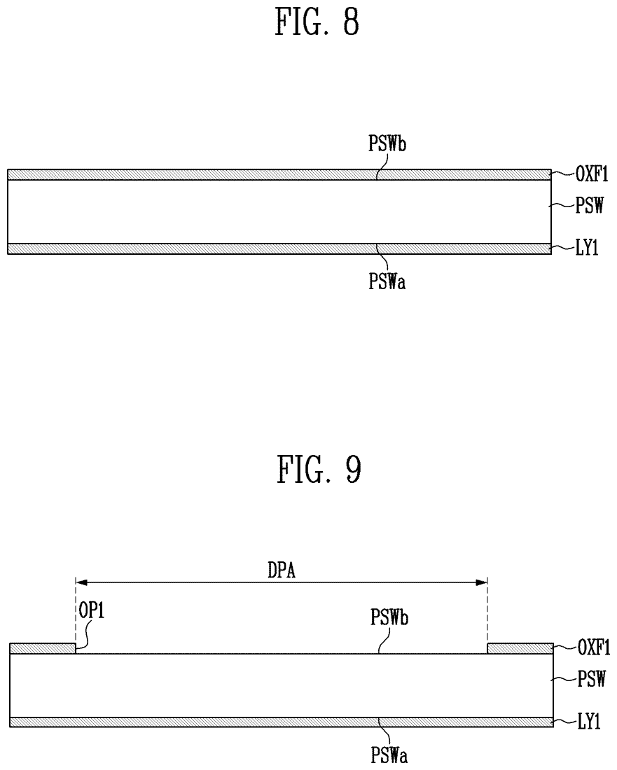

Referring to FIG. 8, a second surface PSWb of the preliminary silicon wafer PSW may be oxidized to form a first oxide layer OXF1. For example, the first oxide layer OXF1 may include silicon oxide.

Referring to FIG. 9, a portion of the first oxide layer OXF1 may be removed to form a first opening OP1. A portion of the second surface PSWb of the preliminary silicon wafer PSW overlapping a doping area DPA may be exposed by the first opening OP1.

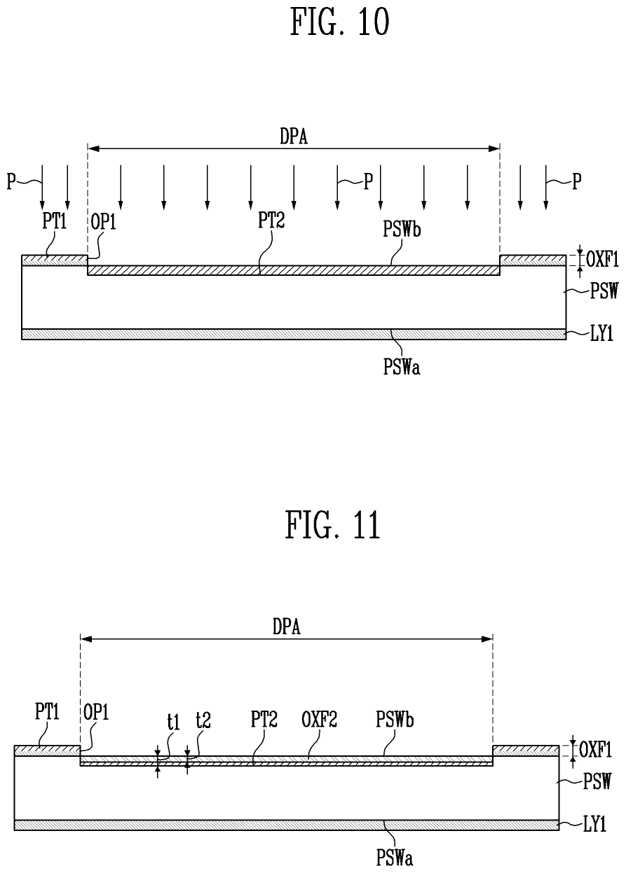

Referring to FIG. 10, a surface of the first oxide layer OXF1 and the doping area DPA of the second surface PSWb of the preliminary silicon wafer PSW may be doped (e.g., entirely doped) with an N-dopant. For example, the surface of the first oxide layer OXF1 and the doping area DPA of the second surface PSWb of the preliminary silicon wafer PSW may be doped in an ion injection process in which the N-dopant is ionized, accelerated, and then injected into a surface. For example, the N-dopant may be at least one of phosphorus (P), arsenic (As), or antimony (Sb). For example, the N-dopant may be phosphorus (P). However, embodiments are not limited thereto. Accordingly, a first portion PT1 formed by doping the surface of the first oxide layer OXF1 and a second portion PT2 formed by doping the doping area DPA of the second surface PSWb of the preliminary silicon wafer PSW may be formed.

Referring to FIG. 11, a second oxide layer OXF2 may be formed by oxidizing the doping area DPA of the second surface PSWb. For example, the second oxide layer OXF2 may include silicon oxide similarly to the first oxide layer OXF1. For example, a thickness t2 of the second oxide layer OXF2 may be formed to be less than a thickness t1 of the second portion PT2. Accordingly, even though the doping area DPA of the second surface PSWb of the preliminary silicon wafer PSW is partially oxidized to form the second oxide layer OXF2, the second portion PT2, which is a doped portion, may remain in the preliminary silicon wafer PSW. However, embodiments are not limited thereto.

The second oxide layer OXF2 may be formed to protect a mask in case that the silicon wafer SW is etched. However, embodiments are not limited thereto, and the second oxide layer OXF2 may be omitted.

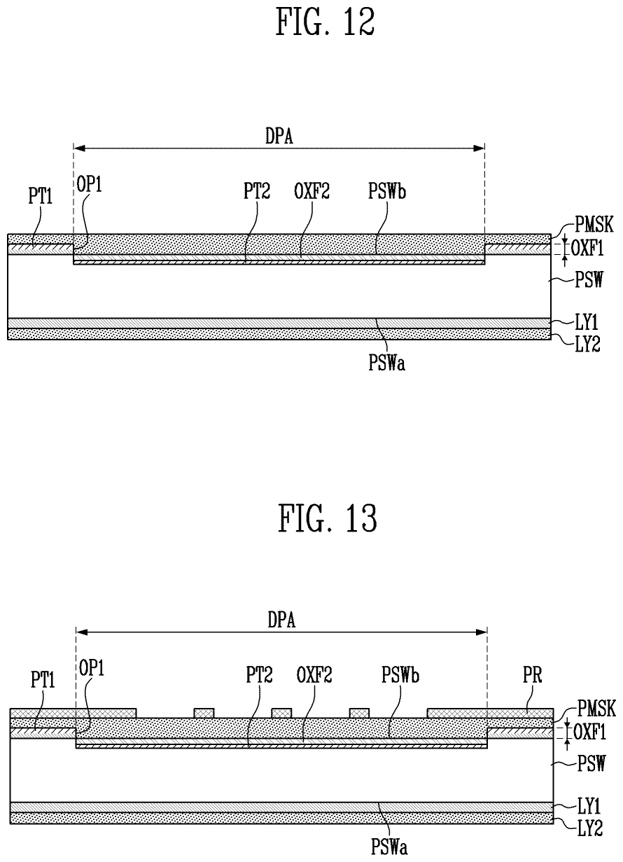

Referring to FIG. 12, a second layer LY2 may be formed under the first layer LY1. A preliminary mask PMSK may be formed (e.g., entirely formed) on the first oxide layer OXF1 and the second oxide layer OXF2. Each of the second layer LY2 and the preliminary mask PMSK may include silicon nitride.

Referring to FIG. 13, a photoresist pattern PR may be formed on the preliminary mask PMSK. The photoresist pattern PR may be formed in a shape of a preset mask by exposing and developing a photoresist layer.

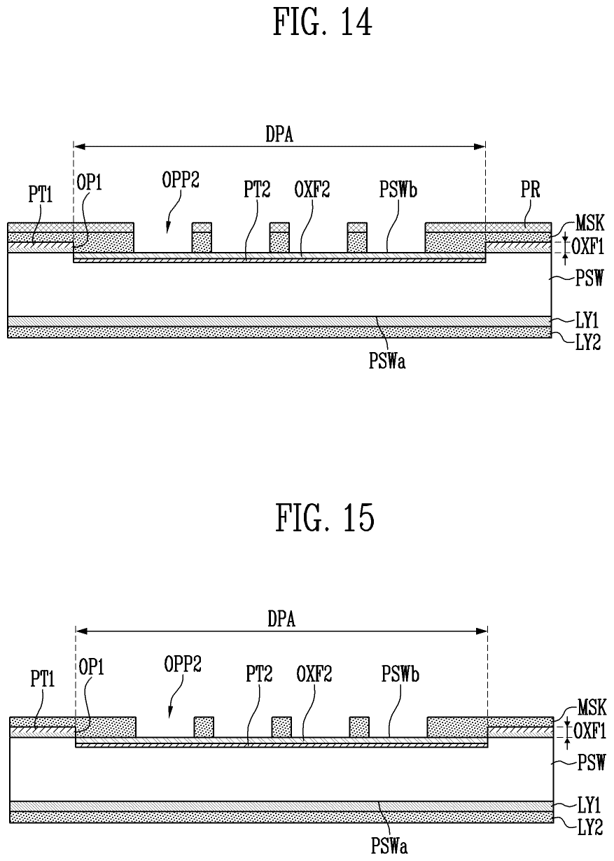

Referring to FIG. 14, the preliminary mask PMSK may be patterned using the photoresist pattern PR. Accordingly, the preliminary mask PMSK may be patterned to form second opening portions OPP2.

Referring to FIG. 15, the photoresist pattern PR may be removed. Accordingly, a mask MSK including second opening portions OPP2 may be formed.

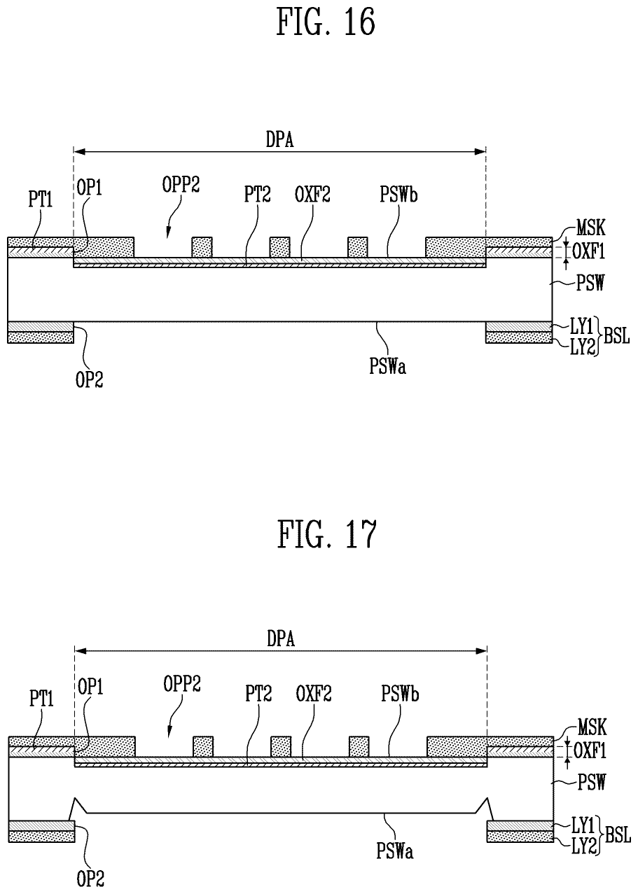

Referring to FIG. 16, a portion overlapping the doping area DPA in each of the first layer LY1 and the second layer LY2 may be patterned. Accordingly, a second opening OP2 overlapping the first opening OP1 may be formed in the first layer LY1 and the second layer LY2. Therefore, a base layer BSL including the first layer LY1 and the second layer LY2 and having the second opening OP2 formed therein may be formed.

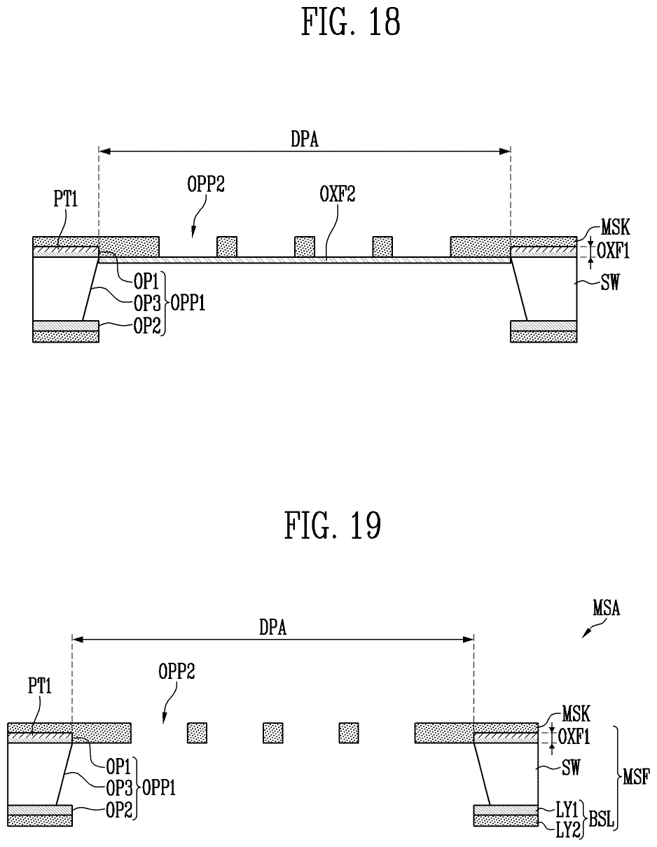

Referring to FIGS. 17 and 18, a portion of the preliminary silicon wafer PSW overlapping the doping area DPA may be patterned to form a silicon wafer SW.

Referring to FIG. 17, an edge portion of the doping area DPA of the preliminary silicon wafer PSW may be etched faster than a center portion. For example, the preliminary silicon wafer PSW may be etched by a wet etching process. Because etchant is in contact with the first surface PSWa of the preliminary silicon wafer PSW, the preliminary silicon wafer PSW may be etched from the edge portion of the doping area DPA of the first surface PSWa of the preliminary silicon wafer PSW.

Referring further to FIG. 18, because the edge portion of the doping area DPA of the first surface PSWa of the preliminary silicon wafer PSW is etched faster than the center portion, the edge portion of the doping area DPA may come into contact with the second portion PT2 before the center portion.

The second portion PT2, which is a portion doped with an N-dopant, may be etched about 2 to 3 times faster than a portion including another intrinsic silicon. Therefore, in case that the edge portion, which is etched first, is in contact with the second portion PT2, the second portion PT2 may be etched at a speed higher than a speed at which the center portion is etched. Accordingly, as the second portion PT2 of the preliminary silicon wafer PSW, which is in contact with the second oxide layer OXF2, is etched, a portion of the preliminary silicon wafer PSW that was in contact with the second oxide layer OXF2 may be removed. Therefore, a portion overlapping the doping area DPA of the preliminary silicon wafer PSW may be quickly removed entirely. Accordingly, a deviation a removal speed for each area in the doping area DPA of the preliminary silicon wafer PSW may be minimized. For example, because the deviation of the removal speed for each area is minimized, a stress difference between the preliminary silicon wafer PSW, the second oxide layer OXF2, and the mask MSK occurring due to a deviation of an etching speed may also be minimized. Accordingly, damage to each of the preliminary silicon wafer PSW, the second oxide layer OXF2, and the mask MSK occurring due to the stress difference may be prevented, and yield of the mask assembly may be improved.

As a portion overlapping the doping area DPA of the preliminary silicon wafer PSW is etched, a third opening OP3 overlapping the first opening OP1 and the second opening OP2 may be formed. Therefore, a silicon wafer SW including the third opening OP3 may be formed. For example, the first to third openings OP1 to OP3 may form a first opening portion OPP1. For example, the first opening portion OPP1 may be formed to overlap second opening portions OPP2.

Referring to FIG. 19, the second oxide layer OXF2 may be removed. As the second oxide layer OXF2 is removed, a mask MSK may be exposed, and a mask frame MSF disposed under the mask MSK may be formed. Therefore, a mask assembly MSA including the mask MSK and the mask frame MSF may be formed.

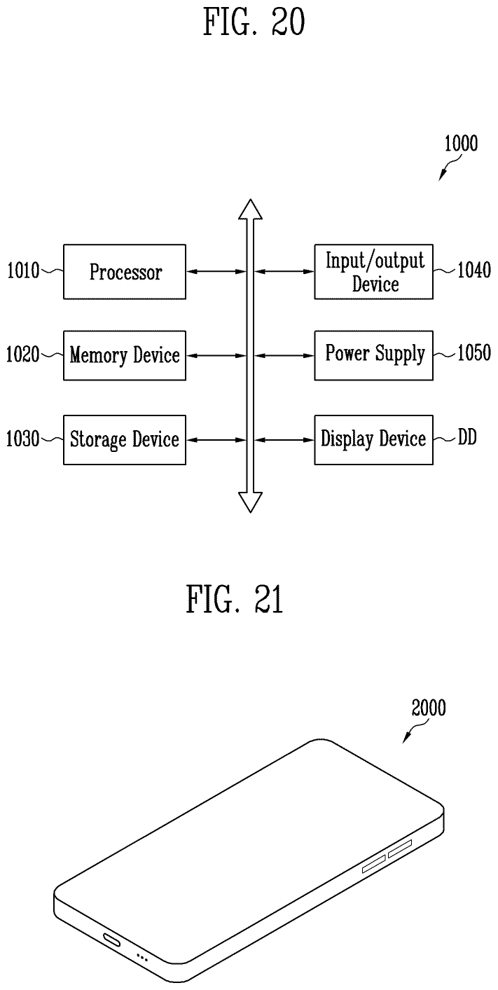

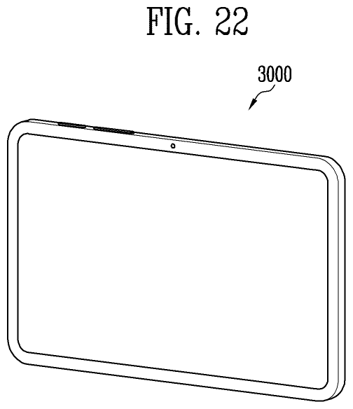

FIG. 20 is a schematic block diagram illustrating an embodiment of an electronic device including the display device of FIGS. 2 and 3. FIG. 21 is a schematic perspective view illustrating an example of a smartphone that may be implemented using the electronic device of FIG. 20. FIG. 22 is a schematic perspective view illustrating an example of a tablet computer that may be implemented using the electronic device of FIG. 20.

Referring to FIG. 20, the electronic device 1000 may include a processor 1010, a memory device 1020, a storage device 1030, an input/output device 1040, a power supply 1050, and a display device DD.

In embodiments, as shown in FIG. 21, the electronic device 1000 may be implemented as the smartphone 2000. In other embodiments, as shown in FIG. 22, the electronic device 1000 may be implemented as the tablet computer 3000. However, this is an example, and the electronic device 1000 is not limited thereto. For example, the electronic device 1000 may be an electronic device (or a computing system) including the above-described display device DD, such as a digital television (TV), a 3D TV, a personal computer (PC), a home appliance, a laptop computer, a mobile phone, a video phone, a smart pad, a smart watch, a head mounted display device, a personal digital assistant (PDA), a portable multimedia player (PMP), a digital camera, a music player, a portable game console, or a navigation system.

The processor 1010 may perform various tasks and calculations. In embodiments, the processor 1010 may include an application processor, a graphic processing unit, a microprocessor, a central processing unit (CPU), or the like. The processor 1010 may be connected to other components of the electronic device 1000 through a bus system. In embodiments, the bus system may include a peripheral component interconnect (PCI) bus. The processor 1010 may provide a data stream to be displayed on the display device DD to the display device DD.

The memory device 1020 may be provided (or formed) as a working memory and/or buffer memory of the electronic device 1000 and/or the processor 1010. In embodiments, the memory device 1020 may include volatile memory devices such as a dynamic random access memory (DRAM), a static random access memory (SRAM), and a mobile DRAM.

The storage device 1030 may store data in response to control of the processor 1010. The storage device 1030 may include a nonvolatile storage medium that maintains data even though power of the electronic device 1000 is cut off. In embodiments, the storage device 1030 may include a solid state drive (SSD), a hard disk drive (HDD), or the like.

The input/output device 1040 may include user input devices such as a keyboard, a keypad, a touchpad, a touchscreen, and a mouse, and output devices such as a speaker and a printer.

The power supply 1050 may supply power required for an operation of the electronic device 1000. For example, the power supply 1050 may be a power management integrated circuit (PMIC). For example, the power supply 1050 may include a battery.

The display device DD may display an image in response to control of the processor 1010. The display device DD may be connected to other components of the electronic device 1000 through a bus system and/or another communication link. The display device DD may be implemented as the display device DD of FIG. 18. The display device DD may display an image on the pixels PXL, and each of the pixels PXL may be formed as shown in FIG. 17 according to an embodiment.

Although the technical spirit of the disclosure has been described in detail in accordance with the above-described embodiments, it should be noted that the above-described embodiments are for the purpose of description and not of limitation. Those skilled in the art can understand that various modifications are possible within the scope of the technical spirit of the disclosure.

The scope of the disclosure is not limited to the details described in the detailed description of the specification, but should be defined by the claims. It is to be construed that all changes or modifications derived from the meaning and scope of the claims and equivalent concepts thereof are included in the scope of the disclosure.

What is claimed is:

1. A mask assembly comprising:
a mask frame including a first opening portion, the mask frame including a first portion doped with an N-dopant; and
a mask disposed on the mask frame and including a plurality of second opening portions overlapping the first opening portion.

2. The mask assembly of claim 1, wherein the first portion is in direct contact with the mask.

3. The mask assembly of claim 1, wherein the mask includes silicon nitride.

4. The mask assembly of claim 1, wherein the mask frame comprises:
a base layer;
a silicon wafer disposed on the base layer; and
an oxide layer disposed on the silicon wafer and including silicon oxide.

5. The mask assembly of claim 4, wherein the first portion is included in the oxide layer.

6. The mask assembly of claim 4, wherein
the oxide layer includes a first opening,
the base layer includes a second opening overlapping the first opening, and
the silicon wafer includes a third opening overlapping the second opening.

7. The mask assembly of claim 6, wherein the first opening portion includes the first, second, and third openings.

8. The mask assembly of claim 4, wherein the base layer comprises:
a first layer disposed on a first surface of the silicon wafer; and
a second layer disposed under the first layer.

9. The mask assembly of claim 8, wherein
the first layer includes silicon oxide, and
the second layer includes silicon nitride.

10. The mask assembly of claim 1, wherein the first portion is doped with phosphorus (P).

11. A method of manufacturing a mask assembly, the method comprising:
forming a mask frame including a first opening portion and including a first portion doped with an N-dopant; and
forming a mask including a plurality of second opening portions overlapping the first opening portion on the mask frame.

12. The method of claim 11, wherein the forming of the mask frame comprises:
forming a preliminary silicon wafer;
forming a first layer including silicon oxide on a first surface of the preliminary silicon wafer;
oxidizing a second surface of the preliminary silicon wafer to form a first oxide layer;
removing a portion of the first oxide layer to form a first opening exposing a doping area of the second surface of the preliminary silicon wafer;
doping a surface of the first oxide layer and the doping area of the second surface of the preliminary silicon wafer with the N-dopant; and
oxidizing the doping area of the second surface to form a second oxide layer.

13. The method of claim 12, wherein the N-dopant is phosphorus (P).

14. The method of claim 12, wherein the forming of the mask comprises:
after forming the second oxide layer,
forming a preliminary mask on the first oxide layer and the second oxide layer;
forming a photoresist pattern on the preliminary mask; and
patterning the preliminary mask using the photoresist pattern to form the mask.

15. The method of claim 14, wherein the forming of the mask frame further comprises:
forming a second layer under the first layer; and
patterning a portion overlapping the doping area in each of the first layer and the second layer to form a second opening overlapping the first opening.

16. The method of claim 15, wherein
the first layer includes silicon oxide, and
the second layer includes silicon nitride.

17. The method of claim 15, wherein the forming of the mask frame further comprises:
after forming the mask,
patterning a portion overlapping the doping area of the preliminary silicon wafer to form a silicon wafer having a third opening overlapping the second opening; and
removing the second oxide layer.

18. An electronic device comprising:
a processor; and
a display device including pixels, and that displays an image on the pixels according to control of the processor,
wherein the display device is formed by a mask assembly comprising:
a mask frame including a first opening portion and including a first portion doped with an N-dopant; and
a mask disposed on the mask frame and including a plurality of second opening portions overlapping the first opening portion.
